(19) United States
(12) Patent Application Publication
(10) Pub. No.: US 2025/0357305 A1
(43) Pub. Date: Nov. 20, 2025

(54) DUAL INTERFACE SILICON STACK

(71) Applicant: Advanced Micro Devices, Inc., Santa Clara, CA (US)

(72) Inventors: Gabriel H. LOH, Bellevue, WA (US); John J. WUU, Fort Collins, CO (US)

(21) Appl. No.: 18/664,233

(22) Filed: May 14, 2024

(51) Int. Cl. H01L 23/50; H01L 21/768; H01L 23/00; H01L 23/498; H01L 23/538; H01L 25/065; H10B 80/00

(52) U.S. Cl. CPC H01L 23/50; H01L 21/76898; H01L 23/49822; H01L 23/5381; H01L 24/14; H01L 25/0652; H01L 2224/1401; H01L 2224/14515; H01L 2924/1431; H01L 2924/1434; H01L 2924/182; H10B 80/00

(57) ABSTRACT

An electronic device, a chip package, and a system comprising the same are disclosed herein. In one example, an electronic device includes a silicon stack. The silicon stack has first side having first electrical connections configured to receive power from a power source, and a second side positioned opposite the first side configured to communicate a first data signal.

### TECHNICAL FIELD

Examples of the present disclosure generally relate to a silicon stack using multiple sides of a silicon stack to route power and data signals to provide an improved electrical interface and power distribution within the silicon stack.

### BACKGROUND

A silicon stack includes two or more integrated circuit (IC) chips vertically stacked on top of each other. The silicon stack further includes power and ground circuitry, data signal circuitry, and interface circuitry that connects the power and signal circuitry to operate an electronic device. Traditionally, silicon stacks have all of the electrical interfaces to connect the power and ground circuitry and the data signal circuitry on one side of the silicon stack. As processing power and signal bandwidth increase, the power requirements for the stacked silicon electronic devices also increases.

An IC device including a silicon stack of vertically stacked IC chips may be referred to as a 3D stacked silicon device. 3D stacked silicon devices, or silicon stacks are used to form memory devices. Silicon stacks provide an increased memory bandwidth, reduced memory latency, reduced data movement power, and an increased component integration density. In existing memory silicon stack devices, all electrical connections are on one side of the stack, often on the side that is attached to a substrate, which provides connections to power, ground, and control signals (e.g., address signals, data signals, and debug signals among others). The increase in bandwidth and power requirements can lead to suboptimal routing for data signal interfaces and power delivery.

There is a limited real estate for routing and electrical connections on a single side of the silicon stack where the interface circuitry resides. Silicon stacks are increasing in capability with increased number of channels and wider data buses, which increases the pressure on the stack interface resources (bumps and signal routing). Using only a single side of the stack for electrical connections limits the operation of the electrical device without significantly increasing the overall size of the electrical device.

Therefore, a need exists for an improved interface for power distribution and data signals in a silicon stack that increases the real estate available for additional electrical connections and improves the routing of power and data signals within an electronic device including the silicon stack and to other electronic devices.

### SUMMARY

An electronic device, a chip package, and a system are disclosed herein. The disclosed technology uses a silicon stack having electrical connections on two sides of the stack to interface with power and data signals. The electrical connections on both sides of the silicon stack may decrease the amount of current necessary to be delivered to the electronic device, improves power delivery to all areas of the electronic device, effectively separates the power and data signals to decrease coupling, and reduces the need for additional resources to run power through the electronic device.

In one example, an electronic device includes a silicon stack. The silicon stack has a first side having first electrical connections configured to receive power from a power source, and a second side positioned opposite the first side configured to communicate a first data signal.

In some examples, the first side has third electrical connections configured to communicate a second data signal. In other examples, the second side has fourth electrical connections configured to receive power from the power source.

In some examples, the first electrical connections are adjacent to the third electrical connections. In other examples, the third electrical connections are disposed between a first portion of the first electrical connections and a second portion of the first electrical connections.

In some examples, the silicon stack is a memory device.

In some examples, the first electrical connections are configured to through-silicon vias (TSVs) disposed within the silicon stack and/or through-mold vias (TMVs) disposed outside of the silicon stack. In some examples the first electrical connections are configured to TSVs disposed within the silicon stack and TMVs disposed outside of the silicon stack. In some examples the second electrical connections are configured to TSVs disposed within the silicon stack and/or TMVs disposed outside of the silicon stack.

In yet another example, a chip package is provided. The chip package includes a silicon stack and a substrate. The silicon stack has first side having first electrical connections configured to receive power from a power source, and a second side positioned opposite the first side configured to communicate a first data signal. The silicon stack is disposed on the substrate.

In yet another example, a system is provided. The system includes a first electronic device, a second electronic device, and a substrate. The first electronic device comprises a silicon stack having a first side having first electrical connections configured to receive power from a power source, and a second side positioned opposite the first side configured to communicate a first data signal. The first electronic device and the second electronic device are disposed on a substrate. The second electronic device is electrically connected to the first electronic device via the substrate.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a top down view of the bottom surface of an embodiment of the electrical connections of electronic device.

FIG. 2 exhibits a cross sectional view of an embodiment of an electronic device having a silicon stack having interfaces with electrical connections on two sides of an electronic device.

FIG. 3 exhibits a cross sectional view of an electronic device having power and ground electrical connections and data signal connections on the top and bottom interface, according to an embodiment.

FIGS. 3A and 3B exhibit partial cross sectional views of potential layouts of the interface of electrical connections of an electronic device, according to some embodiments.

FIGS. 4A, 4B, and 4C exhibit a variety cross sectional views of potential layouts of the interface of electrical connections of an electronic device, according to some embodiments.

FIG. 5 illustrates a cross sectional view of an embodiment of a system of two electronic devices disposed on a substrate wherein one electronic device has interfaces with electrical connections on two sides of the electronic devices, such as but not limited to the electronic devices described herein.

FIG. 6 depicts a flow diagram of a method for operating an integrated circuit (IC) die stack that includes at least a first IC die stacked with a second IC die.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

3D stacked silicon devices, or silicon stacks, are electronic devices which include a stack of vertically stacked IC chips. Silicon stack electronic devices such as graphics processing units (GPU), accelerator devices, and memory devices frequently use silicon stacks to improve the capacity and data transfer of the electronic device. In one example, layers of memory integrated circuit (IC) chips (or dies) can be stacked to increase the overall memory capacity and bandwidth of data transfer of the electronic device. These silicon stack electronic devices can be coupled to other devices, such as a processor via an interposer, to interface, read, and/or write the data stored in the first electronic device. In one example, a silicon stack electronic device is a memory device that includes a stack of multiple memory IC chips. The electronic devices include interface circuitry that is electrically coupleable via an array of electrical connections such as microbumps or solder balls. The electrical connections are separated into two categories, power and ground connections, and control signal and data signal connections.

Existing implementations of 3D silicon stacks utilize electrical connections on only one side of the silicon stack. Typically the electrical connections are on the bottom of the silicon stack, e.g., a side of the silicon stack coupled to an interposer (or substrate), and the power and signal are routed through the silicon stack from those electrical connections.

The challenge in improving electrical devices is to increase the performance and the bandwidth of the devices, such as increasing the number of channels available to transmit data, and to have wider channels increasing the amount of data per transaction in a channel. As the number of channels increases and/or the bandwidth of the channels increases, there is a need for additional power delivery to facilitate the increased data transmission. A key factor in the improved data and power transmission is the overall size of the electronic device. Thus, it is preferable to increase the data and power transmission in a manner which minimizes the increase in overall electronic device size.

In one example, the electrical connections for the power and ground and the signal data of a silicon stack electronic device can be located on both the bottom of the silicon stack, or the side configured to attach to an interposer, and the top of the silicon stack, opposite the bottom. By locating some electrical connections on the top and bottom of the silicon stack, the power distribution can be more centrally located closer to all locations of the chip with less degradation of the power from the point of the power connections to the components being powered. Using both the top and bottom of the silicon stack for electrical connections also allows separation of the power transmission lines and the signal transmission lines, reducing interference such as capacitive or inductive coupling between the lines.

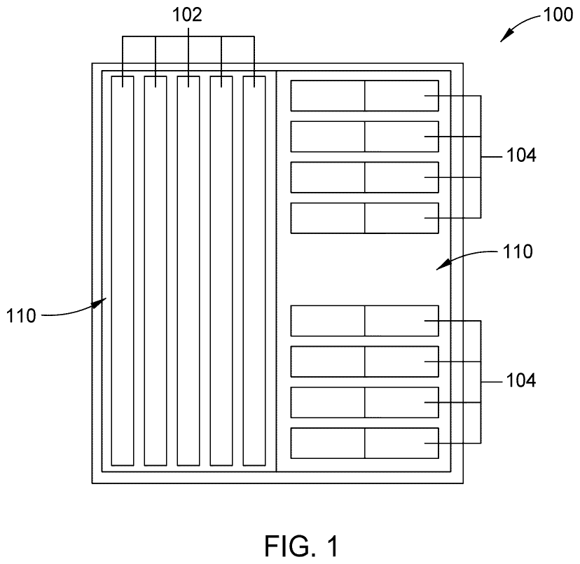

Turning now to FIG. 1, FIG. 1 illustrates a bottom view of the electrical connections of electronic device 100, according to one or more examples. The electronic device 100 includes array of electrical connections consisting of an interface 110 of an array of power and/or ground connections 102 and an array of data signal connections 104. The array of electrical connections may consist of microbumps, solder ball, or another type of electrical connector suitable for power transmission and data transmission from one electronic device to another electronic device. In some examples, an electronic device 100 may be a 3D memory stack device. Data signal connections 104 may include a number of channels, such as for example 16-channels or 32-channels. The number of channels of data signal, in part, determines the amount of power transmission and the number of power and ground connections 102 necessary to operate the electronic device 100.

As the bandwidth and power delivery requirements increase, the interface 110 size will also need to increase to fit the added electrical connections 102, 104. One method to mitigate the size increase of the interface 110 is to re-organize the organization of the electrical connections 102, 104.

In order to increase the amount of data signal channels, the number of data signal connections 104a-b would be doubled and the power and ground connections 102 need to be increased to effectively drive the sufficient power to operate the electronic device 100. High-speed data signals are sensitive to distance between connections and the inductance added by the wire traces, meaning keeping connections shorter maintains the high-speed data transmission, and increasing the length of connections may cause degradation of performance. Power distribution can also be sensitive to distance, as the distance from the source increases, the capacitance and resistance also increases, which can cause a drop in voltage. Power distribution is not as sensitive to the distance between connections as high-speed data transmission.

The distance to connect from the data signal connections 104a to another electronic device, such as a processor via an interposer, connected on the opposite side of the electronic device 100 (e.g. outside of the boundary of the silicon stack 101) may cause significant signal degradation. Increasing the number of data signal connections 104a-b and power and ground connections 102 also significantly increases the size of the interface 110 and therefore the overall size of the electronic device 100. The distance between the channels on connections 104a, 104b complicates the internal routing of the electronic device 100 as the channels on connections 104a, 104b may be located in locations that are detrimental to the routing. Power and ground connections 102a-b may also pose routing challenges outside of the electronic device 100 (e.g. on a silicon interposer) due to the location of the power and ground connections 102a-b and the sensitivity of the data signals and power degradation. Thus, there are challenges of scaling existing implementations of silicon stacks 101 in electronic devices 100 and the need for an improved interface for electrical connections 102, 104.

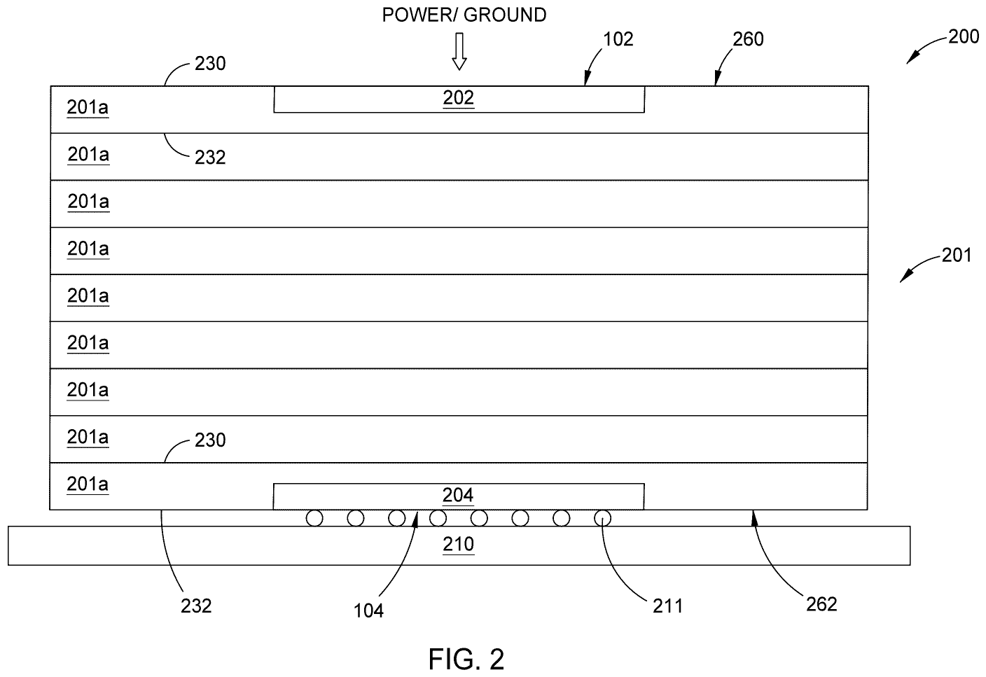

FIG. 2 exhibits an example of a silicon stack electronic device 200 having a stack of two or more layers of IC chips 201a forming a 3D silicon stack 201. At least one or more of the IC chips 201a may be a compute IC die, a photonics IC die, a memory IC die, chiplet or other type of IC die. The layers of IC chips 201a of the silicon stack 201 may be connected across an interconnect using microbumps, hybrid bonding, or similar techniques. In one example, each of the IC chips 201a includes a first side 230 and a second side 232. The first side 230 of one IC chip 201a is coupled to the second side 232 of an adjacent IC chip 201a. In the silicon stack 201, the first side 230 of the IC chip 201a defines one side 260 of silicon stack 201, while the second side 232 of the IC chip 201a defines the opposite side 262 of silicon stack 201. The electronic device 200 comprises interface circuitry 202, 204 each having electrical connections 102, 104 on two sides 260, 262 opposite of each other of the silicon stack 201. While the figures show 8 IC chips 201a in the silicon stack 201, in other examples of a silicon stack 201, a different number of IC chips 201a may be used. The silicon stack 201 may include any combination of the same or different types of IC chips 201a. In some examples, the IC chips 201 can include one or more memory chips, logic controller chips, processor chips, accelerator chips, or other types of IC chips. In one example, the electronic device 200 is a high bandwidth memory device and the IC chips 201a are memory IC chips. In some examples, the silicon stack 201 may be connected to a substrate 210, such as a printed circuit board, via solder balls, hybrid bonding, or via socket 211. In other examples, the substrate 210 may be one of a bridge die, an interposer stacked on a package substrate, or a package substrate.

In the example shown in FIG. 2, the top interface circuitry 202 is used for power delivery and the power and ground connections 102, and the bottom interface 204 is used for the high-speed data signals and/or other data connections 104.

Silicon memory stacks, such as for example the electronic device 200, may be used to for high-speed transmission of data. For example, silicon memory stacks may transmit hundreds of gigabits per second, wherein each high-speed data signal connection 104 may transmit multiple gigabits per second per connection 104. High-speed data signals can degrade significantly with long routing distances. The top interface 202, may have longer distances to travel to, which is suitable for power and ground connections 102, which do not have the same magnitude of signal integrity sensitivity as high-frequency and data signals. There are also methods to decrease the degradation of power delivery, which can be implemented in the silicon stack 201 of the electronic device 200, such as increasing the amount of metal used to drive the power delivery through the silicon stack 201.

The bottom interface 204 may be used for routing data signals, which are more sensitive to routing distance and inductance of the wire. By having high-speed data electrical connections 104 at the bottom interface 204, the length of the signal routing can be maintained or reduced, having short routing distances. Data signals and power and ground signals are separated by a distance in order to mitigate capacitive or inductive coupling between the data signals and the power and ground signals. Separating the interfaces 202, 204 allows signal routing free from capacitive and inductive coupling by routing wires directly out of the electronic device 100 without spacing out or lengthening the wires to avoid the routing of the power and ground connections 102.

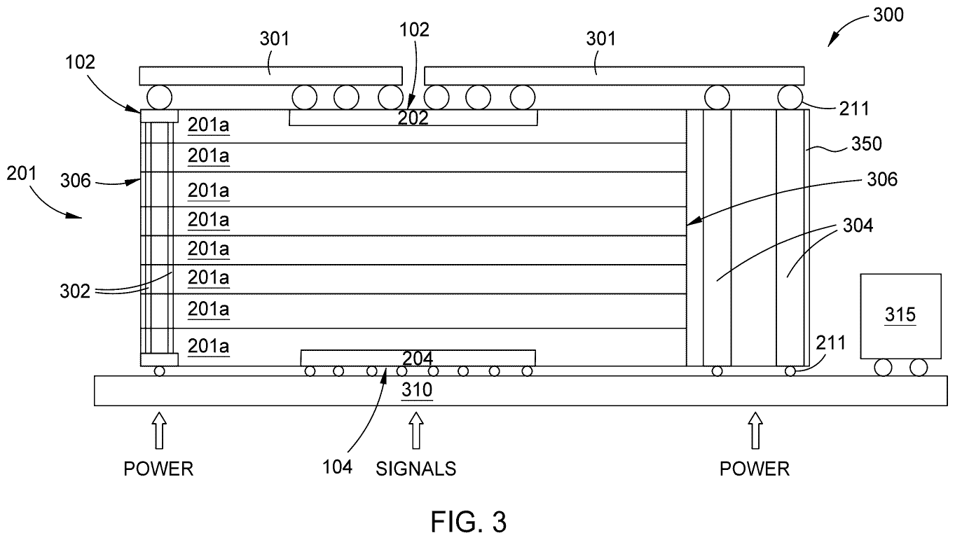

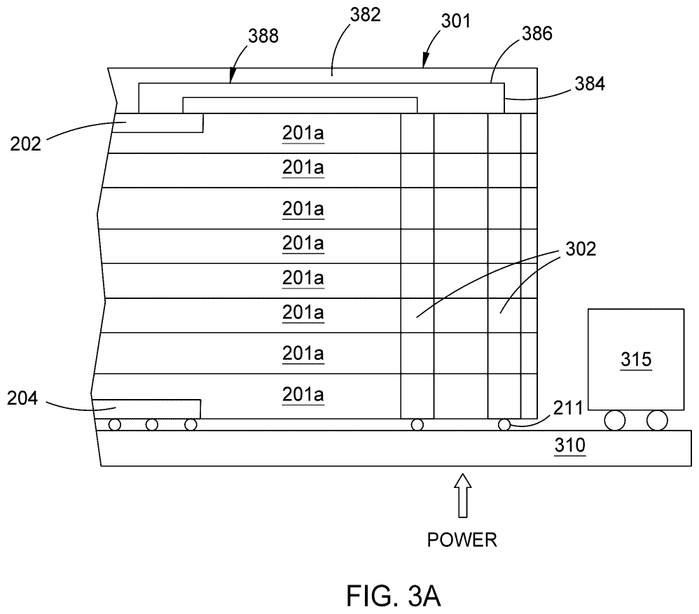

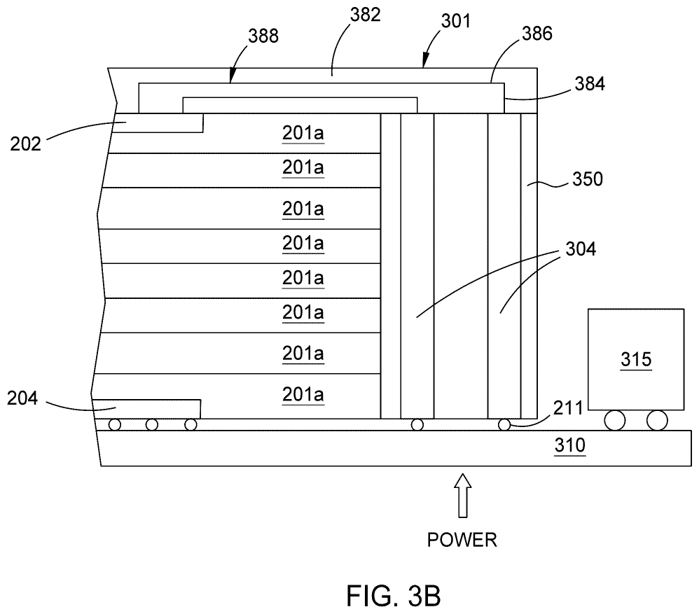

Power can be delivered to the top interface 202 of the electronic device 100 through a variety of means, or a combination thereof. FIG. 3 exhibits an example of an electronic device 300 having power and ground electrical connections 102 and data signal connections 104 on the bottom interface 204, and power and ground electrical connections 102 on the top interface 202. The electronic device 300 may be connected to a substrate 310 via solder balls, hybrid bonding, or via socket 211. In some examples, the substrate 310 may be a printed circuit board. In other examples, the substrate 310 may be one of a bridge die, an interposer stacked on a package substrate, or a package substrate.

In one example, power can be delivered from a power source 315 connected to the substrate 310 to the electronic device 300 via through-silicon vias (TSVs) 302 in the electronic device. The power source may be connected to the substrate 310 via solder balls, hybrid bonding, or via socket. TSVs 302 are areas of conductive material that are formed in holes, or vias, in each IC chip 201a layer of silicon of the silicon stack 201. TSVs 302 are vertically aligned and pass signals through each of the IC chips 201a. TSVs 302 provide electrical connections through that respective layer of silicon to connect to other layers of IC chips 201a in the silicon stack 201. In some examples, TSVs 302 are used to make connections between two or more IC chips of the silicon stack 201. In some examples TSVs 302 may be placed in each IC chip of the silicon stack 201 arranged in a manner to make connections between the top of a substrate to the redistribution layer (RDL) at the bottom of a substrate, for example from the top interface circuitry 202 to the bottom interface circuitry 204. The RDL generally includes patterned conductive traces (for example, interconnected lines and via) disposed in a plurality of dielectric layers. According to an example, TSVs 302 can be used to transmit the power in a location of the electronic device that mitigates negative effects that the power has on the data signals transmitted in other TSVs 302 or otherwise throughout the electronic device, mitigating negative impacts to the performance such as capacitive or inductive coupling between the data signals and the power. In some examples, TSVs 302 carrying power can be concentrated closer to the edge of the electronic device 100, away from the routing of the data signals.

In one or more examples, power can be delivered to the power and ground electrical connections 102 at the top interface circuitry 202 via through-mold vias (TMVs) 304. TMVs 304, similar to TSVs 302, act like a conduit to deliver the power of the power and ground connections 102 through a material, for example molding compound 350, dispose outside of the silicon stack 201 of the electrical device 200. TMVs 304 are conductive elements that run outside the sides 306 of the silicon stack 201 of the electronic device 300, such as through a material that surrounds the electronic device 300 (not shown). In some examples, TMVs 304 comprise a conductive material formed in a via in the material that surrounds the electronic device 300. In some examples, the conductive material can be a metal material. In some examples the material that surrounds the electronic device 300 is a molding compound. After molding, a via is formed in the mold to form the TMV 304. The via is filled with the conductive material through which circuitry can be coupled. In one example, TMVs 304 can contain more conductive material than TSVs 302. In some examples TMVs 304 can be used for delivering higher current power than TSVs 302 due to the amount of conductive material in the TMV 304 versus the TSV 302. In one or more examples, the capacitance of a TMV 304 may limit the ability of a TMV to be used to be included within high-speed data interfaces as a TMV may not be able to provide adequate signal speeds and densities for the high-speed data interfaces.

Electronic devices, such as electronic device 300, may include one or more TSVs 302, one or more TMVs 304 or a combination of TSVs 302 and TMVs 304. In some examples electronic devices may not include any TSVs 302 or TMVs 304. In some examples the TSVs 302 may be used to for power delivery to transmit power to the power and ground connections 102. In another example the TSVs 302 may be used to for power delivery to transmit power to the power and ground connections 102 and data signals to the data connections 104. In yet another example TSVs 302 may be used for power delivery to transmit power to power and ground connections 102 and TMVs 304 may be used in conjunction for power delivery to transmit power to power and ground connections 102. In yet another example, TSVs 302 may be used for power delivery to transmit power to the power and ground connections 102 and data signals to the data connections 104 and TMVs 304 may be used in conjunction for power delivery to transmit power to the power and ground connections 102.

The placement of TSVs 302 and TMVs 304 is flexible and the arrangement of each is based on the individual IC design. In some examples there may be one or more TSVs 302 and no TMVs 304. In other examples there may be one or more TMVs 304 and no TSVs 302. In some examples, the TMVs 304 may be on either side 306 of the electronic device 200. The TMVs 304 can functionally be in any area of the molding compound surrounding the electronic device 200 which fits the area and IC design requirements.

Similarly, the placement of TSV's 302 is based around the IC design requirements of the electronic device 200. In some examples, TSVs 302 can be located on the left side 306 of the circuit, such as in FIG. 3. However, TSVs 302 can also be located on the right side 306, or any available area between the sides 306 within the electronic device 200 that meet the physical and electrical requirements for a TSV 302 for the given IC design.

In the example shown in FIG. 3, after power is delivered vertically via the TSVs 302, the TMVs 304, or otherwise, the power proceeds laterally from the top of each TSV 302 or TMV 304 to the power and ground connections 102. Lateral connections 301 can be made through one or more of back-side metal routings, routings formed in an RDL, and/or routing patterned on the top of the silicon stack 201, or any other method of making electrical connections.

FIGS. 3A and 3B depicts lateral connections 301 in the form of an RDL formed on the silicon stack 201. The RDL comprising the lateral connections 301 includes routings 388 formed in two or more dielectric layers 382. The routings 388 include electrically conductive lines 386 and vias 384 patterned in the dielectric layers 382 to electrically couple the TSVs 302 and TMVs 304 to the top interface circuitry 202 that receives the power and/or ground signals.

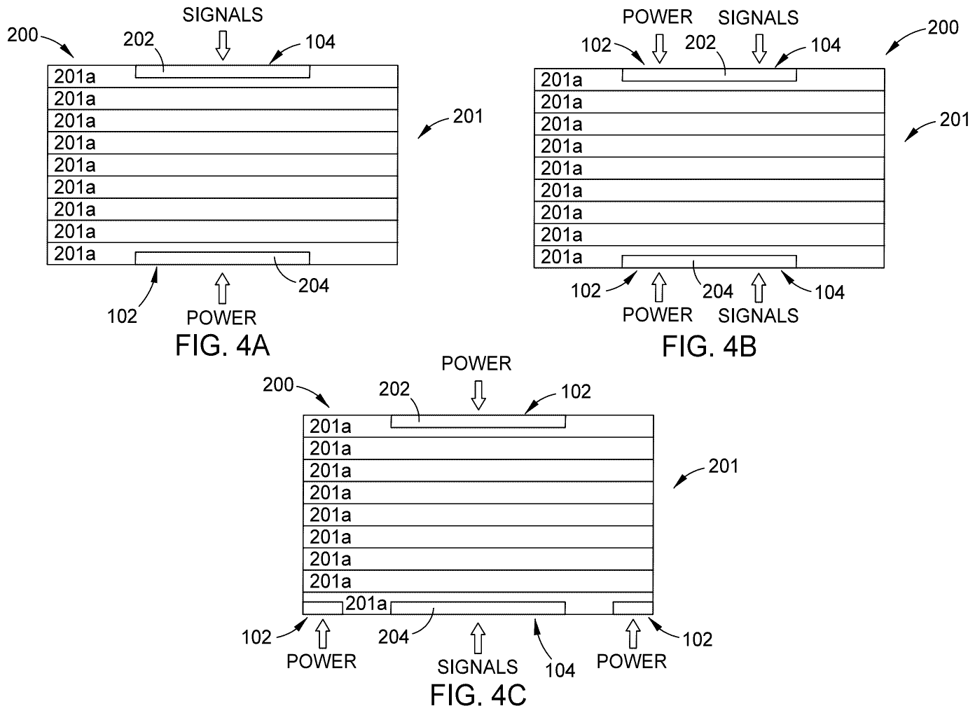

FIGS. 4A, 4B, and 4C show examples of the electronic device 200 having top interface circuitry 202 and bottom interface circuitry 204 comprised of a power and ground connections 102, data signal connections 104, and combinations thereof on each the top interface circuitry 202 and bottom interface circuitry 204. The integration and packing of the electronic device 200, along with the function, may determine layout of the interface circuitry 202, 204. In the example shown in FIG. 4A, the data signal connections 104 are on the top interface circuitry 202 and the power and ground connections 102 are on the bottom interface circuitry 204. In some examples, the power and ground connections 102 may be on the bottom interface circuitry 204 of an electronic device 200, rather than on the top interface circuitry 202 for integration with other system-on-chip (SOC) components.

In the example shown in FIG. 4B, the top interface circuitry 202 is comprised of a combination of power and ground connections 102 and data signal connections 104 and the bottom interface circuitry 204 is comprised of a combination of power and ground connections 102 and data signal connections 104.

In the example shown in FIG. 4C, the top interface circuitry 202 is comprised of power and ground connections 102, and the bottom interface circuitry 204 is comprised of a combination of power and ground connections 102 and data signal connections 104. In some examples, the layout in 4C is used to deliver power to the lower half of the silicon stack 201 through shorter or less restrictive paths directly from the bottom interface circuitry 204. In some examples, having separate power delivery on the top interface circuitry 202 and the bottom interface circuitry 204 reduces the amount of current needed to be delivered to each power and ground connection 102 or to other IC chips 201a in the silicon stack 201. In other examples, having separate power delivery on the top interface circuitry 202 and the bottom interface circuitry 204 may further reduce IR drop. In yet another example, having separate power delivery on the top interface circuitry 202 and the bottom interface circuitry 204 may reduce the amount of TSVs 302 and TMVs 304 used within an electronic device.

FIGS. 4A-C illustrates a variety of the potential layouts of electronic device 200, however, the layout of an electronic device 200 is not limited to the examples shown. In one example, the power and ground connections 102 and data signal connections 104 in FIG. 4B are side by side on the top interface circuitry 202 and on the bottom interface circuitry 204, but could be spaced out on each interface circuitry 202, 204 such as, for example, the power and ground connections 102 and data signal connections 104 on the bottom interface circuitry 204 of FIG. 4C. In another example, the layout of the respective electrical connections 102, 104 in FIG. 4B can side by side on the top interface circuitry 202 and spaced out such as the electrical connections 102, 104 of FIG. 4C on the bottom interface circuitry 204. The examples shown in FIGS. 4A-C are intended to show example embodiments, but are not intended to limit the potential layouts of each of the interface circuitry 202, 204.

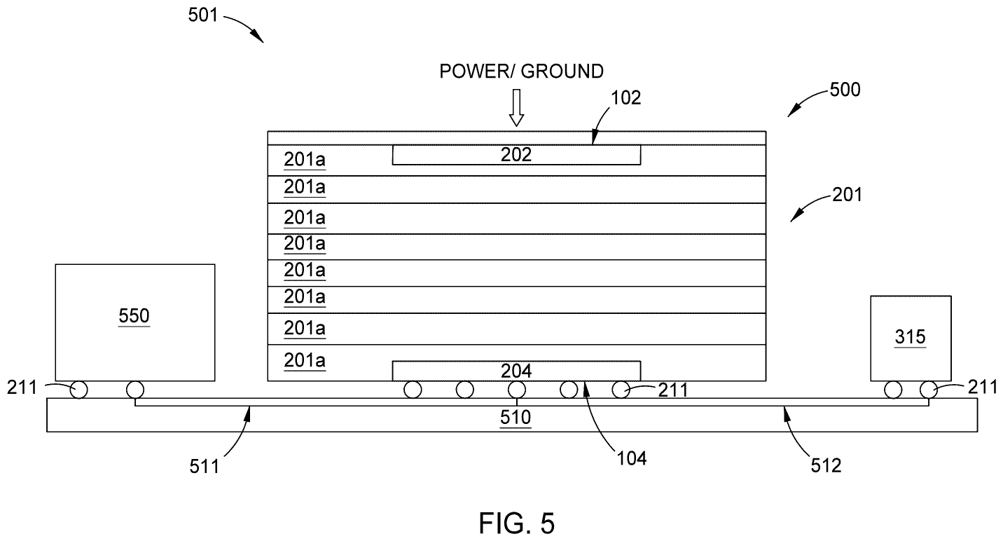

FIG. 5 exhibits an electronic device 500, such as electronic device 200, disposed on a substrate 510 and connected to a second electronic device 550 via circuitry 511 in the substrate 510 and a power source 315 via circuitry 512 in the substrate 510. Electronic device 550 may be an integrated circuit or another silicon stack device, such as electronic device 200. In some examples electronic device 550 may be an FPGA. In another example electronic device 550 may be an integrated circuit such as a CPU or GPU. In other examples, the electronic device 550 may be any type of IC that can functionally interface with electronic device 500 in a system. The electronic devices 500, 550 and power source 315 may be connected to the substrate 510 via solder balls, hybrid bonding, or via socket 211. In some examples, the substrate 510 may be a printed circuit board. In other examples, the substrate 510 may be one of a bridge die, an interposer stacked on a package substrate, or a package substrate.

The interface circuitry 202 of the silicon stack 201 is interface with lateral connections 301. The lateral connections 301 may be connected to power via at least one or both of TSVs 302 and TMVs 304 as illustrated in FIGS. 3, 3A and 3B.

The silicon stack 201 may be integrated with other components or electronic devices through a variety of methods. In some examples integration of the silicon stack 201 may be done via 2.5D stacking on interposers. In other examples integration of the silicon stack 201 with other components or electronic devices may be done via fan-out based packaging, 3D stacking with microbumps, 3D stacking with hybrid bonding, or silicon bridge technologies. In some examples integration may be done with one of the listed techniques or a combination thereof. In some examples the silicon stack 201 may be a memory device which can be integrated with other SOC components via, for example, 2.5D stacking on interposers.

In some examples, the electronic device 100, 200, 300, 500 may be a memory device. The memory devices may consist of one or more memory technologies including dynamic random-access memory (DRAM), static random-access memory (SRAM), phase-change memory (PCM), ferroelectric random-access memory (FeRAM), spin-transfer torque magnetic random-access memory (STT-MRAM), embedded dynamic random-access memory (eDRAM), a combination thereof, or any other known memory technologies. In examples consisting of memory devices, one or more layers (e.g., IC chips 201a) of the silicon stack 101, 201 may include other functionality such as compute or processing. The electronic device 100, 200, 300, 500 may also be any other type of electronic device utilizing a silicon stack. For example the electronic device 100, 200, 300, 500 could be a logic plus memory stack, a logic stack, or a mixed memory stack. While a single memory device such as electronic device 100, 200, 300, 500 is illustrated, in other examples, the electronic device 100, 200, 300, 500 may include one or more silicon stack devices described. In one exemplary example, the electronic device 500 is configured as a high bandwidth memory device, wherein the silicon stack 201 is comprised of IC chips 201a in the form of memory IC dies, coupled through the substrate 510 to the electronic device 550, the electronic device 550 configured as one or more compute/logic IC dies such as a CPU or GPU.

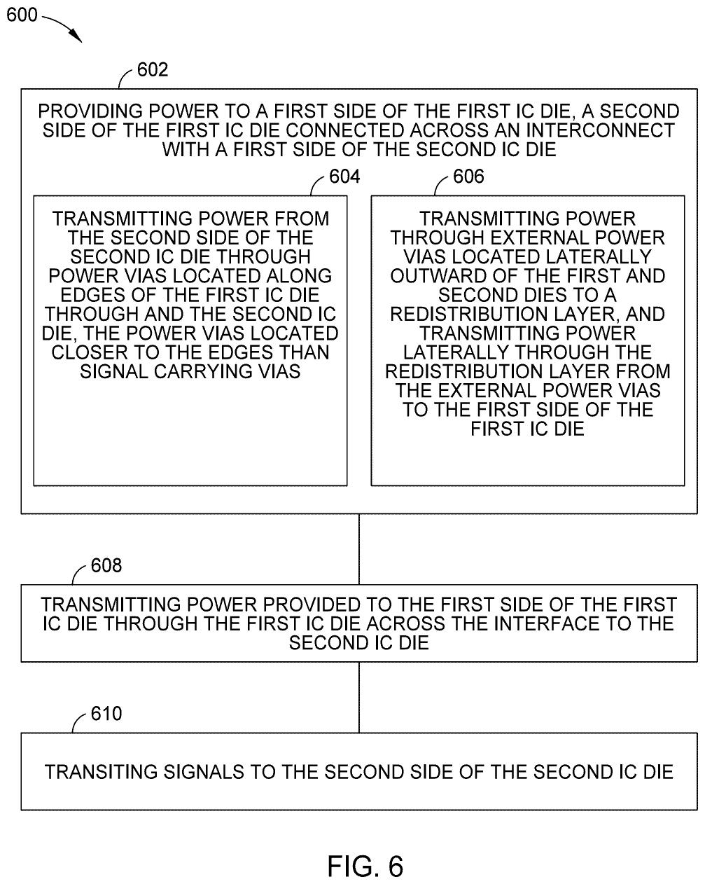

FIG. 6 depicts a flow diagram of a method 600 for operating an integrated circuit (IC) die stack that includes at least a first IC die stacked with a second IC die. The method 600 may be performed utilizing one or more of the electronic device 100, 200, 300, 500 described above, or other similar electronic device.

The method 600 beings at operation 602 by providing power to a first side of the first IC die. A second side of the first IC die is connected across an interconnect with a first side of the second IC die. Power may be provided to the first side of the first IC die in a number of ways. For example, operation 602 may be performed via operation 604 in which power is transmitted from the second side of the second IC die through power vias located along edges of the first IC die through and the second IC die. The power vias are located closer to the edges than the signal carrying vias. Alternatively or in addition to operation 604, operation 602 may be performed via operation 606 in which power is transmitted from the second side of the second IC die through external power vias located laterally outward of the first and second dies to a redistribution layer. The power is laterally transmitted through the redistribution layer from the external power vias to the first side of the first IC die.

The method 600 also includes operation 608 in which power is transmitted from the first side of the first IC die through the first IC die across the interface to the second IC die.

The method 600 also includes operation 610 in which signals are transmitted to a second side of the second side of the second IC die. The signals are also transmitted from the first side of the first IC die through the first IC die across the interface to the second IC die.

While the foregoing is directed to specific examples, other and further examples may be devised without departing from the basic scope thereof, and the scope thereof is determined by the claims that follow.

What is claimed is:

1. An electronic device comprising:
a silicon stack comprising:
a first side having first electrical connections disposed thereon, the first electrical connections configured to receive power from a power source; and
a second side positioned opposite the first side and having a second array of electrical connections disposed thereon, the second electrical connections configured to communicate a first data signal.

2. The electronic device of claim 1, wherein the first side has third electrical connections, the third electrical connections configured to communicate a second data signal.

3. The electronic device of claim 2, wherein the second side has fourth electrical connections, the fourth electrical connections configured to receive the power from the power source.

4. The electronic device of claim 2, wherein the first electrical connections are adjacent to the third electrical connections.

5. The electronic device of claim 2, wherein the third electrical connections are disposed between a first portion of the first electrical connections and a second portion of the first electrical connections.

6. The electronic device of claim 1 wherein the silicon stack is a memory device.

7. The electronic device of claim 1 wherein the first electrical connections are coupled to through-silicon vias (TSVs) disposed within the silicon stack.

8. The electronic device of claim 1 wherein the first electrical connections are coupled to through-mold vias (TMVs) disposed outside of the silicon stack.

9. The electronic device of claim 1 wherein the first electrical connections are coupled to TSVs disposed within the silicon stack and TMVs disposed outside of the silicon stack.

10. The electronic device of claim 1 wherein the second electrical connections are coupled to TSVs disposed within the silicon stack and/or TMVs disposed outside of the silicon stack.

11. The electronic device of claim 1 further comprising:
a substrate, wherein the silicon stack is disposed on the substrate.

12. The electronic device of claim 11, wherein the substrate comprises one of a bridge die, an interposer stacked on a package substrate, or a package substrate.

13. The electronic device of claim 11, wherein the substrate comprises a printed circuit board.

14. A method for operating an integrated circuit (IC) die stack that includes at least a first IC die stacked with a second IC die, the method comprising:
providing power to a first side of the first IC die, a second side of the first IC die connected across an interconnect with a first side of the second IC die;
transmitting power provided to the first side of the first IC die through the first IC die across the interconnect to the second IC die;
transiting signals to a second side of the second IC die.

15. The method of claim 14, wherein providing power to the first side of the first IC die further comprises:
transmitting power from the second side of the second IC die through power vias located along edges of the first IC die through and the second IC die, the power vias located closer to the edges than signal carrying vias.

16. The method of claim 14, wherein providing power to the first side of the first IC die further comprises:
transmitting power through external power vias located laterally outward of the first and second IC dies to a redistribution layer; and
transmitting power laterally through the redistribution layer from the external power vias to the first side of the first IC die.

17. A package device comprising:
a first electronic device comprised of a silicon stack, the silicon stack comprising:
a first surface having first electrical connections disposed thereon, the first electrical connections configured to receive power from a power source; and
a second surface positioned opposite the first surface and having second electrical connections disposed thereon, the second electrical connections configured to communicate a data signal;
a substrate, wherein the first electronic device is disposed on the substrate; and
a second electronic device disposed on the substrate, wherein the second electronic device is electrically connected to the first electronic device via the substrate.

18. The package device of claim 17, wherein two or more integrated circuit devices are disposed on the substrate and are electrically connected to the silicon stack via the substrate.

19. The package device of claim 17, wherein the first electronic device includes one of a CPU, GPU, or FPGA.

20. The package device of claim 17, wherein the first and/or second electrical connections are electrically connected to the substrate via TSVs disposed within the silicon stack and/or via TMVs disposed outside of the silicon stack.
